(19) United States
(12) Patent Application Publication
(10) Pub. No.: US 2025/0156743 A1
(43) Pub. Date: May 15, 2025

(54) ARRANGEMENT FOR QUANTUM COMPUTING

(71) Applicant: IQM FINLAND OY, Espoo (FI)

(72) Inventors: Hermanni HEIMONEN, Espoo (FI); Juha VARTIAINEN, Espoo (FI); Olli-Pentti SAIRA, Espoo (FI); Kuan Yen TAN, Espoo (FI); Juha HASSEL, Espoo (FI)

(21) Appl. No.: 18/837,702

(22) PCT Filed: Feb. 23, 2022
(86) PCT No.: PCT/FI2022/050121

§ 371 Date: Aug. 12, 2024

(51) Int. Cl. G06N 10/40; H10N 60/12

(52) U.S. Cl. CPC G06N 10/40; H10N 60/12

(57) ABSTRACT

According to an embodiment, an arrangement for quantum computing comprises: a plurality of quantum computing units, each quantum computing unit comprising a plurality of qubits arranged to perform a quantum computation according to a plurality of control signals and to provide at least one output signal according to a result of the quantum computation; a control unit for providing the plurality of control signals; a signal division arrangement for transmitting the plurality of control signals to the plurality of quantum computing units, wherein the signal division arrangement is configured to divide each control signal to each quantum computing unit; wherein the control unit is configured to cause each quantum computing unit to execute a separate instance of the quantum computation; and a read-out unit configured to obtain the at least one output signal from each quantum computing unit and perform at least one statistical operation based on the output signals, thus obtaining an ensemble quantum computation result.

### TECHNICAL FIELD

The present disclosure relates to quantum computing, and more particularly to an arrangement for quantum computing and to a quantum computing system.

### BACKGROUND

It has been predicted that quantum computing will deliver exponential speed-ups compared to a classical computing in specific tasks. However, the results from the quantum computing may be non-deterministic due to the nonidealities in the quantum computing unit, or from the principles of certain methodologies used in quantum computing. Thus, a quantum computation typically needs to be executed multiple times in order to obtain a meaningful result. This can significantly increase the overall runtime of quantum computation and thus hinder the overall performance of quantum computing and limits application area. While a single quantum processor may comprise a number of qubits the complexity of the wiring and difficulties in calibration and fabrication of copies of high quality quantum processors has typically limited the number of quantum processors with in since set up to one or few at most.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

It is an objective to provide an arrangement for quantum computing and to a quantum computing system. The foregoing and other objectives are achieved by the features of the independent claims. Further implementation forms are apparent from the dependent claims, the description and the figures.

According to a first aspect, an arrangement for quantum computing comprises a plurality of quantum computing units, each quantum computing unit comprising a plurality of qubits arranged to perform a quantum computation according to a plurality of control signals provided to the quantum computing unit and to provide at least one output signal according to a result of the quantum computation; a control unit for providing the plurality of control signals to the plurality of quantum computing units; a signal division arrangement for transmitting the plurality of control signals originating from the control unit to the plurality of quantum computing units, wherein the signal division arrangement is configured to divide each control signal in the plurality of control signals originating from the control unit to each quantum computing unit in the plurality of quantum computing units; wherein the control unit is configured to, via the plurality of control signals and the signal division arrangement, cause each quantum computing unit in the plurality of the quantum computing units to execute a separate instance of the quantum computation; and a read-out unit configured to: obtain the at least one output signal from each quantum computing unit in the plurality of quantum computing units; perform at least one statistical operation based on the output signals, thus obtaining an ensemble quantum computation result. The arrangement can, for example, obtain a result for the quantum computation faster.

In an implementation form of the first aspect, each quantum computing unit in the plurality of quantum computing units corresponds to a quantum processing unit, QPU, a core in a multi-core QPU, or a sub-unit of a QPU. The arrangement can, for example, be implemented with various levels of integration.

In another implementation form of the first aspect, the signal division arrangement is configured to divide each control signal in the plurality of control signals originating from the control unit to each quantum computing unit in the plurality of quantum computing units using at least one T-junction, at least one power divider, at least one Wilkinson power divider, at least one directional coupler, and/or at least one hybrid coupler. The arrangement can, for example, efficiently divide radio frequency control signals to the plurality of quantum computing units.

In another implementation form of the first aspect, the arrangement further comprises a tuning arrangement configured to adjust at least one property of the plurality of control signals divided by the signal division arrangement, wherein the at least one property comprises at least one of: frequency, amplitude, phase, and/or relative timing. The arrangement can, for example, fine-tune the control signals according to the properties of each quantum computing unit.

In another implementation form of the first aspect, the tuning arrangement further comprises at least one voltage-controlled attenuator configured to adjust at least one control signal in the plurality of control signals divided by the signal division arrangement. The arrangement can, for example, efficiently fine-tune radio frequency control signals.

In another implementation form of the first aspect, the at least one voltage-controlled attenuator comprises at least one high-electron mobility transistor, at least one tuneable reactive impedance element, at least one superconducting quantum interference device, and/or at least one varactor diode. The arrangement can, for example, efficiently fine-tune radio frequency control signals.

In another implementation form of the first aspect, the output signals from the plurality of quantum computing units are time-multiplexed and the read-out unit is further configured to obtain the output signal from each quantum computing unit in the plurality of quantum computing units according to the time-multiplexing. The arrangement can, for example, transmit the output signals from the quantum computing units to the read-out unit with a reduced number of signal lines.

In another implementation form of the first aspect, the arrangement further comprises delay lines coupled to the plurality of quantum computing units and configured to time-multiplex the output signals from the plurality of quantum computing units. The arrangement can, for example, efficiently time-multiplex the output signals via the delay lines.

In another implementation form of the first aspect, the read-out unit further comprises a summing arrangement and wherein the read-out unit is configured to perform the at least one statistical operation based on the output signals by coherently summing the output signals via the summing arrangement. The arrangement can, for example, efficiently perform the at least one statistical operation via the coherent summing.

In another implementation form of the first aspect, each quantum computing unit in the plurality of quantum computing units further comprises a plurality of frequency tuning elements configured to tune qubit frequencies of the plurality of qubits according to a frequency tuning signal. The arrangement can, for example, fine-tune the qubit frequencies.

In another implementation form of the first aspect, each quantum computing unit in the plurality of quantum computing units further comprises a plurality of capacitance tuning elements configured to tune capacitances of the plurality of qubits according to a capacitance tuning signal. The arrangement can, for example, fine-tune the qubit capacitances.

In another implementation form of the first aspect, the plurality of qubits comprises superconducting qubits.

In another implementation form of the first aspect, the at least one statistical operation comprises at least one of: a mean, a variance, and/or cross-entropy.

In another implementation form of the first aspect, the arrangement further comprises a cryostat, wherein the plurality of quantum computing units and the signal division arrangement are located inside the cryostat. The arrangement can, for example, reduce the number of signal lines needed to be run into the cryostat.

According to a second aspect, a quantum computing system comprises a plurality of arrangements according to the first aspect.

Many of the attendant features will be more readily appreciated as they become better understood by reference to the following detailed description considered in connection with the accompanying drawings.

### DESCRIPTION OF THE DRAWINGS

In the following, example embodiments are described in more detail with reference to the attached figures and drawings, in which:

FIG. 1 illustrates a schematic representation of an arrangement for quantum computing according to an embodiment;

FIG. 2 illustrates a schematic representation of an arrangement for quantum computing further comprising a tuning arrangement according to an embodiment;

FIG. 3 illustrates a schematic representation of an arrangement for quantum computing further comprising delay lines according to an embodiment;

FIG. 4 illustrates a schematic representation of a qubit and a frequency tuning element according to an embodiment; and

FIG. 5 illustrates a schematic representation of a control unit according to an embodiment.

In the following, like reference numerals are used to designate like parts in the accompanying drawings.

### DETAILED DESCRIPTION

In the following description, reference is made to the accompanying drawings, which form part of the disclosure, and in which are shown, by way of illustration, specific aspects in which the present disclosure may be placed. It is understood that other aspects may be utilised, and structural or logical changes may be made without departing from the scope of the present disclosure. The following detailed description, therefore, is not to be taken in a limiting sense, as the scope of the present disclosure is defined be the appended claims.

For instance, it is understood that a disclosure in connection with a described method may also hold true for a corresponding device or system configured to perform the method and vice versa. For example, if a specific method step is described, a corresponding device may include a unit to perform the described method step, even if such unit is not explicitly described or illustrated in the figures. On the other hand, for example, if a specific apparatus is described based on functional units, a corresponding method may include a step performing the described functionality, even if such step is not explicitly described or illustrated in the figures. Further, it is understood that the features of the various example aspects described herein may be combined with each other, unless specifically noted otherwise.

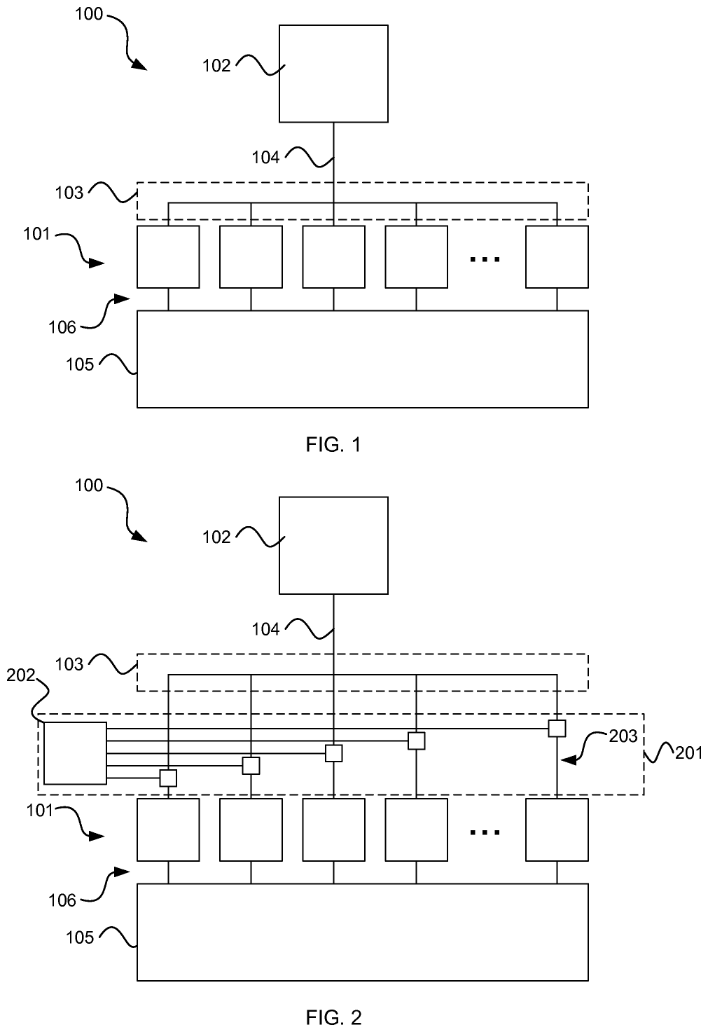

FIG. 1 illustrates a schematic representation of an arrangement for quantum computing according to an embodiment.

According to an embodiment, the arrangement 100 comprises a plurality of quantum computing units 101, each quantum computing unit comprising a plurality of qubits arranged to perform a quantum computation according to a plurality of control signals provided to the quantum computing unit and to provide at least one output signal according to a result of the quantum computation.

The plurality of qubits may comprise, for example, superconducting qubits, such as transmon qubits, flux qubits, charge qubits, phase qubits, or fluxonium qubits.

Although some embodiments may be disclosed herein with reference to a certain type of qubit, these qubit types are only exemplarily. In any embodiment disclosed herein, the plurality of qubits may be implemented in various ways and using various technologies.

Each control signal in the plurality of control signals can control, for example, coupling between qubits, initialization of a qubit, a state of a qubit, and/or any other property of a qubit needed for performing the quantum computation.

The control signals may comprise, for example, radio frequency (RF) signals or optical signals depending on the implementation of the plurality of quantum computing units 101.

The output signals may also be referred to as read-out signals or similar.

A control signal may also be referred to as a control voltage, a control pulse, or similar.

The arrangement 100 may further comprise a control unit 102 for providing the plurality of control signals 104 to the plurality of quantum computing units 101.

Although the embodiment of FIG. 1 illustrates only one signal line originating from the control units 102, this is only for clarity of illustration. There may be any number of signal lines originating from the control unit 102. For example, if N control signals are needed for each quantum computing unit in the plurality of quantum computing units 101, the plurality of control signals 104 may comprise N control signals and there may be a corresponding signal line, originating from the control unit 102, for each control signal.

The arrangement 100 may further comprise a signal division arrangement 103 for transmitting the plurality of control signals 104 originating from the control unit 102 to the plurality of quantum computing units 101. The signal division arrangement 103 may be configured to divide each control signal in the plurality of control signals 104 originating from the control unit 102 to each quantum computing unit in the plurality of quantum computing units 101.

For example, if N control signals are needed for each quantum computing unit, the plurality of control signals 104 may comprise N control signals. The signal division arrangement 103 can divide each of the N control signals for each quantum computing unit in the plurality of quantum computing units 101 so that the N control signals are provided to each quantum computing unit. Thus, if there are M quantum computing units in the plurality of quantum computing units 101, the signal division arrangement 103 may be configured to output NxM control signals.

The signal division arrangement 103 may also be referred to as a fan-out arrangement, a signal distribution arrangement, a distributor, a one-to-many arrangement or similar.

The control unit 102 may be configured to, via the plurality of control signals 104 and the signal division arrangement 103, cause each quantum computing unit in the plurality of the quantum computing units 101 to execute a separate instance of the quantum computation.

Each quantum computing unit in the plurality of quantum computing units 101 may be nominally similar. Thus, each quantum computing unit may execute the quantum computation in a similar fashion.

Since the signal division arrangement 103 can divide each control signal in the plurality of control signals 104 to each quantum computing unit in the plurality of quantum computing units 101, each quantum computing unit can execute a separate instance of the quantum computation. However, the result of the quantum computation may be non-deterministic, for example, due to the nonidealities in the quantum computing unit, or due to the principles of certain quantum computing methods, whence each quantum computing unit may not provide the same result to the quantum computation.

An instance of the quantum computation may refer to a separate execution of the quantum computation. Each instance can execute the quantum computation separately from the other instances. Each instance of the quantum computation may not produce the same result due to the non-deterministic nature of quantum computing.

Each quantum computing unit in the plurality of quantum computing units 101 may be a separate unit in the sense that there is no quantum coherence shared over the plurality of quantum computing units 101. Thus, each quantum computing unit can execute the quantum computation independently of each other.

The quantum computation can also be referred to as a quantum algorithm, a quantum circuit, or similar.

The arrangement 100 may further comprise a read-out unit 105 configured to obtain the at least one output signal 106 from each quantum computing unit in the plurality of quantum computing units 101 and perform at least one statistical operation based on the output signals 106, thus obtaining an ensemble quantum computation result.

Since the result of the quantum computation may be non-deterministic in each quantum computing unit in the plurality of quantum computing units 101, the readout unit 105 may need to perform statistical operations on the results in order to obtain the ensemble quantum computation result.

The ensemble quantum computation result may refer to a computation result obtained based on the result of each instance of the quantum computation. For example, the ensemble quantum computation result may correspond to an average over the results of the different instances.

According to an embodiment, the at least one statistical operation comprises at least one of: a mean, a variance, and/or cross-entropy.

According to an embodiment, the signal division arrangement 103 is configured to divide each control signal in the plurality of control signals 104 originating from the control unit 102 to each quantum computing unit in the plurality of quantum computing units 101 using at least one T-junction, at least one power divider, at least one Wilkinson power divider, at least one directional coupler, and/or at least one hybrid coupler.

The components for dividing each control signal in the plurality of control signals 104 disclosed above are only exemplary. Alternatively, the signal division arrangement 103 may be configured to divide each control signal in the plurality of control signals 104 originating from the control unit 102 to each quantum computing unit in the plurality of quantum computing units 101 using any other type of one or more signal dividers.

The arrangement 100 can speed up the quantum computation through operating the plurality of quantum computing units 101 substantially simultaneously instead of, for example, repeating the same quantum computation many times on single quantum computing unit.

The arrangement 100 can run many similar (ideally identical) quantum computing units and perform the collecting of statistics, over the quantum computing unit ensemble instead of, for example, over time. For example, to achieve precision le-3 requires one million samples. Instead of running the same quantum computation for 17 minutes on one quantum computing unit, the same averaging can be done on 1 million quantum computing units in one shot in one millisecond. This may be beneficial for, for example, variational quantum algorithms, where a computation may need to be repeated thousands or more times with varying parameters. The arrangement 100 can enable feasible execution times for such an algorithm when considering, for example, high-performance computing integration and trading data between classical and quantum computing steps. Another example is high-frequency trading in finance applications, where a fraction of a second of wall clock time may be available for decision making. Although the quantum computing algorithms may be powerful in analysing financial data, previously they could not be used for this purpose since the repetition of the algorithm took too much time.

The plurality of quantum computing units 101 can be placed in one or more dilution refrigerators. The plurality of quantum computing units 101 can be fed with similar control signals and their outputs can be readout separately and post-processed, such as averaged, by the read-out unit 105.

In some embodiments, the signal division arrangement 103 can be placed in one or more dilution refrigerators. A dilution refrigerator may also be referred to as a cryostat.

To overcome the large number of control signal lines needed to operate a large number of quantum computing units, the arrangement 100 comprises the fan-out arrangement 103, via which the plurality of control signals 104 can be distributed to each quantum computing unit in the plurality of quantum computing units 101.

The control signals 104 can be high frequency, such as multiple gigahertz or terahertz, electromagnetic signals, such as RF signals or optical signals. The generation of such signals can be a technically complex task. The signal division arrangement 103 can reduce the need for multiple high frequency signal sources, signal lines, and/or other electronics, and thus reduce the technical complexity of the arrangement 100.

The signal division arrangement 103 can comprise dividers through which a single input signal can be divided into a plurality of paths addressing the qubits in different quantum computing units in the plurality of quantum computing units 101. The signal division can be done in a variety of ways. The different implementations can have different signal matching properties, cross-coupling properties, losses, physical size, and accessible frequency bands.

For example, the dividers can comprise T-pieces performing 1:2 divisions of RF signals, or more general dividers performing 1:N divisions. The ports of the dividers can be non-matched. A further generalization of a 1:2 divider is a Wilkinson power divider matched at all ports yet possessing microwave loss mechanisms. The division can also be done with a directional coupler such as a 3 dB hybrid. Generalizations and/or combinations of the examples above are also viable, as well as cascading in many divider stages to produce more outputs.

The signal division arrangement 103 can further comprise impedance matching circuits, filters, isolators, attenuators or any other signal conditioning elements to improve matching, noise rejection, and/or isolation of different ports.

In embodiments where the plurality of quantum computing units 101 are based on, for example, nitrogenvacancy (NV) centre qubits, ion trap qubits, and/or neutral atoms, such as Rydberg atoms, qubits, the control signals 104 can comprise coherent light from lasers and the signal division arrangement 103 can comprise, for example, one or more beam splitters. The lasers can be in different wavelength ranges for the aforementioned technologies.

According to an embodiment, each quantum computing unit in the plurality of quantum computing units 101 corresponds to a quantum processing unit (QPU) a core in a multi-core QPU, or a sub-unit of a QPU.

According to an embodiment, the arrangement 100 further comprises a cryostat, and the plurality of quantum computing units 101 and the signal division arrangement 103 are located inside the cryostat. Thus, the number of signal lines needed to be run into the cryostat can be reduced, since the signal division arrangement 103 can divide the signals inside the cryostat. The control unit 102 can be located outside the cryostat.

The features disclosed herein can be implemented in various different integration levels. For example, different QPU cores can be on a same chip or the QPU cores can be on different chips in a single package. The package can be based on connecting the chips by wire bonding, or there can be a flip-chip solution with one or more carrier chips connecting to one or more QPU cores. The carrier chip can contain all or some microwave engineering solutions disclosed herein. Instead of the carrier chip, a printed circuit board (PCB) may comprise the chips.

FIG. 2 illustrates a schematic representation of an arrangement 100 for quantum computing further comprising a tuning arrangement 201 according to an embodiment.

Due to, for example, manufacturing-related differences in the plurality of quantum computing units 101, there may be a need to fine-tune the control signals after the signal division arrangement 103.

According to an embodiment, the arrangement 100 further comprises a tuning arrangement 201 configured to adjust at least one property of the plurality of control signals divided by the signal division arrangement 103. The at least one property may comprise at least one of: frequency, amplitude, phase, and/or relative timing.

For example, in the embodiment of FIG. 2, the tuning arrangement 201 comprises a tuning unit 202 and a plurality of tuning elements 203 coupled to the tuning unit 202. Although only a single tuning element 203 is depicted for each quantum computing unit in the embodiment of FIG. 2. There may be, for example, a separate tuning element 203 for each for each control signal outputted by the signal division arrangement 103.

In some embodiments, the tuning unit 202 and the control unit 102 may be implemented by a single device. In some other embodiments, there may be a tuning unit 202 for each quantum computing unit in the plurality of quantum computing units 101.

According to an embodiment, the tuning arrangement 201 further comprises at least one voltage-controlled attenuator configured to adjust at least one control signal in the plurality of control signals divided by the signal division arrangement 103.

According to an embodiment, the at least one voltage-controlled attenuator comprises at least one high-electron mobility transistor, at least one tuneable reactive impedance element, at least one superconducting quantum interference device, and/or at least one varactor diode.

The tuning arrangement 201 may comprise, for example, voltage-controlled attenuators via which amplitude of the control signals can be adjusted. Voltage controlled attenuators may be implemented via, for example, high-electron mobility transistors (HEMTs) used as voltage-controlled resistors possibly complemented by passive resistors. Alternatively, the attenuators can comprise tuneable reactive impedance elements implemented via superconductive quantum interference devices (SQUIDs) or SQUID arrays or circuits based on varactor diodes. In some embodiments, a precise phase control may be needed whence phase shifters based on above-mentioned reactive elements may also be used.

In some embodiments, the arrangement 100 may further comprise a second tuning arrangement for the output signals 106. Any disclosure herein in relation to the tuning arrangement 201 may apply also to the second tuning arrangement.

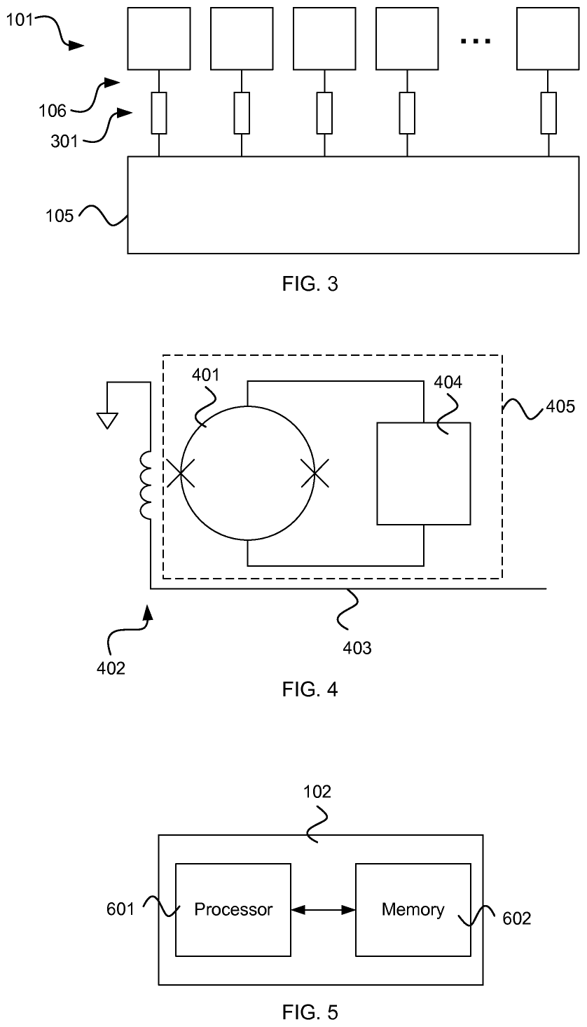

FIG. 3 illustrates a schematic representation of an arrangement 100 for quantum computing further comprising delay lines 301 according to an embodiment.

According to an embodiment, the output signals 106 from the plurality of quantum computing units 101 are time-multiplexed and the read-out unit 105 is furthe configured to obtain the output signal from each quantum computing unit in the plurality of quantum computing units 101 according to the time-multiplexing.

According to an embodiment, the arrangement 100 further comprises delay lines 301 coupled to the plurality of quantum computing units 101 and configured to time-multiplex the output signals 106 from the plurality of quantum computing units.

The qubit readout can be arranged by time-multiplexing, i.e., separating the output signals/pulses in time using, for example, delay lines. The physical length of each delay line can be controlled using, for example, high-inductance metamaterials such as those based on Josephson junctions or transduction to acoustic waves. The delay lines 301 can also be made tuneable by, for example, using magnetic flux controlled Josephson metamaterials.

FIG. 4 illustrates a schematic representation of a qubit and a frequency tuning element according to an embodiment.

The small fabrication discrepancies between the qubits in the plurality of quantum computing units 101 and other quantum computing unit elements and changing environmental conditions can require in-situ tuning.

According to an embodiment, each quantum computing unit in the plurality of quantum computing units 101 further comprises a plurality of frequency tuning elements configured to tune qubit frequencies of the plurality of qubits according to a frequency tuning signal.

For example, each qubit in the plurality of qubits may be coupled to a corresponding frequency tuning element. For superconducting qubits implemented using superconducting quantum interference devices (SQUIDs) this can be done by magnetic flux controlling the Josephson coupling energy, and thus the qubit frequency with DC or radio frequency signals.

Each qubit may have a ground state |g>. Herein, the ground state may refer to a quantum state of the qubit with the lowest energy.

Each qubit may further have at least one excited state. The at least one excited state may comprise a lowest excited state |e>. Herein, the lowest excited state may refer to a quantum state of the qubit with the second lowest energy.

The ground state and the lowest excited state of a qubit may correspond to the computational basis of the qubit. For example, the ground state |g> may correspond to the |0> state of the qubit and the lowest excited state |e) may correspond to the |1> state of the qubit or vice versa. Other quantum states of a qubit may be referred to as non-computational states.

The energy gap between the ground state and the lowest excited state may correspond to a resonance frequency of the qubit. The energy gap may also be referred to as the qubit energy, and the corresponding frequency as the qubit frequency.

In the embodiment of FIG. 4, a qubit 405 comprises a SQUID 401 and a capacitive circuit 404. For the SQUID 401, there is a corresponding frequency tuning element 402. The frequency tunning element 402 is electrically coupled to a signal line 403. The frequency tuning signal can be provided via the signal line 403. By feeding the frequency tuning signal into the signal line 403, the qubit frequency of the qubit 405 can be adjusted. This may be referred to a flux tuning, where the magnetic flux caused by the frequency tuning element 402 causes the qubit frequency of the corresponding qubit 405 to shift.

In other embodiments, two or more qubits can be implements by combining a SQUIDs 401 and a capacitive circuit 404 in a similar fashion as in the embodiment of FIG. 4. For each qubit 405, there may be a corresponding frequency tuning element 402 comprising, for example, a resonator. The resonators can be electrically coupled to a signal line 403. The frequency tuning signal can be provided via the signal line 403. By feeding a signal comprising a frequency corresponding to a resonance frequency of a resonator, the qubit frequency of the corresponding qubit 405 can be adjusted. Since each resonator can have a different resonance frequency, each resonator can be addressed using the same signal line 403 by choosing the frequency of the addressing signal appropriately.

The embodiments disclosed herein are only examples of frequency tuning of the qubits and the frequency tuning can be implemented in various other ways. For example, each qubit can comprise a SQUID tuning loop and the frequency tuning signal comprise a direct current (DC) signal configured to change the DC magnetic flux threading the SQUID tuning loop.

According to an embodiment, each quantum computing unit in the plurality of quantum computing units 101 further comprises a plurality of capacitance tuning elements configured to tune capacitances of the plurality of qubits according to a capacitance tuning signal.

For example, each qubit in the plurality of qubits may be coupled to a corresponding capacitance tuning element. Each capacitance tuning element may be configured to tune the capacitance of the corresponding qubit in response to a corresponding capacitance tuning signal. The capacitance tuning signal can be provided by, for example, the control unit 102 or by any other device/unit/module.

The capacitance tuning elements can compensate for small variations in the charging energy of the qubits, which can affect the spectrum of the non-computational states of the qubit and thereby the fidelity of entangling two-qubit gate operations. Each capacitance tuning element can comprise, for example, a metallic plate affixed to a piezoelectric actuator.

For example, a transmon qubit can comprise two metallic (superconducting) electrodes connected with a Josephson junction. The qubit capacitance is then the electrical capacitance between the two electrodes, which is determined by the geometrical arrangement of the electrodes and nearby dielectrics. If the geometry is deformed, the qubit capacitance will change. The deforming of the geometry can be implemented using, for example, a third movable metallic electrode. The third metallic electrode can be move using, for example, a piezoelectric element controlled by the capacitance tuning signal.

According to an embodiment, the read-out unit 105 further comprises a summing arrangement and the read-out unit 105 is configured to perform the at least one statistical operation based on the output signals 106 by coherently summing the output signals 106 via the summing arrangement.

For example, the summing arrangement can comprise at least one summing element. The output signals 106 can be summed using at least one summing element. The implementation of the at least one summing element can depend on the implementation of the plurality of quantum computing units 101. For example, if the plurality quantum computing units 101 comprise superconducting qubits, the output signals 106 may comprise RF signals. In such a case, the at least one summing element may comprise, for example, one or more RF combiners. If the plurality of quantum computing units 101 comprise NV qubits, ion trap qubits, or neutral atom qubits, the output signals 106 are optical signals. In such cases, the at least one summing element can comprise any component capable of summing optical signals, such as one or more optical couplers, optical combiners etc.

In some embodiments, the output signals are coherently summed before amplification. A benefit of this may be that only one amplifier chain is needed after the summing. Alternatively, the output signal may be coherently summed after amplification. The summing of the output signals can correspond to taking a mean of the output signals.

Each quantum computing unit in the plurality of quantum computing units 101 can comprise one or more output lines. Each output line may provide a corresponding output signal. Each output line can allow reading out the state of each qubit in a subset of qubits using frequency multiplexing.

Each output line can comprise a readout chain. A readout chain can comprise, for example, an amplification chain, a digital signal processor (DSP), and a discriminator that assigns a binary outcome (“0” or “1”) to each qubit measurement.

If the statistical operation is an average of each individual qubit readout, the statistical operation can be performed at any point in the readout chain or by counting the fraction of “1” measurement out-comes.

In embodiments requiring only ensemble-averaged single-qubit readout results, the output signals 106 from each quantum computing unit can be coherently summed before the amplification chain. This can be implemented by, for example, coupling the readout resonators of all quantum computing units into the same microwave feedline and correcting for amplitude and phase misalignments between quantum computing units by the aforementioned tuneable elements.

Alternatively, one can evaluate an expectation value of an arbitrary function of a measurement bitstring. The measurement bitstring can comprise a binary outcome for each qubit in a quantum computing unit. In this case, a separate readout chain may be required for each readout line of each quantum computing unit. Each execution instance of the quantum computation results in a new bitstring. The collection of bitstrings can be used as the output of a sampling problem. From the bitstring samples, one can calculate, for example, the cross-entropy. The cross-entropy can be used in, for example, cross-entropy benchmarking (XEB), which can compare often each bitstring is observed experimentally with its corresponding ideal probability computed via simulation on a classical computer.

In some embodiments, the read-out unit 105 can apply error correction to the output signals before performing the at least one statistical operation. The error correction can be such that it can be applied at this stage based on measurement results without requiring quantum operations conditional on the measurement results.

FIG. 5 illustrates a schematic representation of a control unit 102 according to an embodiment.

The control unit 102 may comprise at least one processor 601. The at least one processor 601 may comprise, for example, one or more of various processing devices, such as a co-processor, a microprocessor, a digital signal processor (DSP), a processing circuitry with or without an accompanying DSP, or various other processing devices including integrated circuits such as, for example, an application specific integrated circuit (ASIC), a field programmable gate array (FPGA), a microprocessor unit (MCU), a hardware accelerator, a special-purpose computer chip, or the like.

The control unit 102 may further comprise a memory 602. The memory 602 may be configured to store, for example, computer programs and the like. The memory 602 may comprise one or more volatile memory devices, one or more non-volatile memory devices, and/or a combination of one or more volatile memory devices and nonvolatile memory devices. For example, the memory 602 may be embodied as magnetic storage devices (such as hard disk drives, magnetic tapes, etc.), optical magnetic storage devices, and semiconductor memories (such as mask ROM, PROM (programmable ROM), EPROM (erasable PROM), flash ROM, RAM (random access memory), etc.).

The control unit 102 may further comprise other components not illustrated in the embodiment of FIG. 6. The control unit 102 may comprise, for example, an input/output bus for connecting the control unit 102 to other devices. Further, a user may control the control unit 102 via the input/output bus. The user may, for example, control quantum computation operations performed by the arrangement 100 via the control unit 102 and the input/output bus.

The control unit 102 may further comprise appropriate signal sources for generating a controlling the control signals 104. For example, the control units 102 may comprise at least one RF signal source and/or at least one optical signal source, such as at least one laser.

When the control unit 102 is configured to implement some functionality, some component and/or components of the control unit 102, such as the at least one processor 601 and/or the memory 602, may be configured to implement this functionality. Furthermore, when the at least one processor 601 is configured to implement some functionality, this functionality may be implemented using program code comprised, for example, in the memory.

The control unit 102 may be implemented at least partially using, for example, a computer, some other computing device, or similar.

Any range or device value given herein may be extended or altered without losing the effect sought. Also any embodiment may be combined with another embodiment unless explicitly disallowed.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item may refer to one or more of those items.

The steps of the methods described herein may be carried out in any suitable order, or simultaneously where appropriate. Additionally, individual blocks may be deleted from any of the methods without departing from the spirit and scope of the subject matter described herein. Aspects of any of the embodiments described above may be combined with aspects of any of the other embodiments described to form further embodiments without losing the effect sought.

The term ‘comprising’ is used herein to mean including the method, blocks or elements identified, but that such blocks or elements do not comprise an exclusive list and a method or apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification.

1. An arrangement for quantum computing, comprising:
a plurality of quantum computing units, each quantum computing unit comprising a plurality of qubits arranged to perform a quantum computation according to a plurality of control signals provided to the quantum computing unit and to provide at least one output signal according to a result of the quantum computation;
a control unit for providing the plurality of control signals to the plurality of quantum computing units;
a signal division arrangement for transmitting the plurality of control signals originating from the control unit to the plurality of quantum computing units, wherein the signal division arrangement is configured to divide each control signal in the plurality of control signals originating from the control unit to each quantum computing unit in the plurality of quantum computing units;
wherein the control unit is configured to, via the plurality of control signals and the signal division arrangement, cause each quantum computing unit in the plurality of quantum computing units to execute a separate instance of the quantum computation; and
a read-out unit configured to:
obtain the at least one output signal from each quantum computing unit in the plurality of quantum computing units; and
perform at least one statistical operation based on the output signals, thus obtaining an ensemble quantum computation result.

2. The arrangement according to claim 1, wherein each quantum computing unit in the plurality of quantum computing units corresponds to a quantum processing unit, QPU, a core in a multi-core QPU, or a sub-unit of a QPU.

3. The arrangement according to claim 1, wherein the signal division arrangement is configured to divide each control signal in the plurality of control signals originating from the control unit to each quantum computing unit in the plurality of quantum computing units using at least one T-junction, at least one power divider, at least one Wilkinson power divider, at least one directional coupler, and/or at least one hybrid coupler.

4. The arrangement according to claim 1, further comprising a tuning arrangement configured to adjust at least one property of the plurality of control signals divided by the signal division arrangement, wherein the at least one property comprises at least one of: frequency, amplitude, phase, and/or relative timing.

5. The arrangement according to claim 4, wherein the tuning arrangement further comprises at least one voltage-controlled attenuator configured to adjust at least one control signal in the plurality of control signals divided by the signal division arrangement.

6. The arrangement according to claim 5, wherein the at least one voltage-controlled attenuator comprises at least one high-electron mobility transistor, at least one tuneable reactive impedance element, at least one superconducting quantum interference device, and/or at least one varactor diode.

7. The arrangement according to claim 1, wherein the output signals from the plurality of quantum computing units are timemultiplexed and the read-out unit is further configured to obtain the at least one output signal from each quantum computing unit in the plurality of quantum computing units according to the time-multiplexing.

8. The arrangement according to claim 7, further comprising delay lines coupled to the plurality of quantum computing units and configured to timemultiplex the output signals from the plurality of quantum computing units.

9. The arrangement according to claim 1, wherein the read-out unit further comprises a summing arrangement and wherein the readout unit is configured to perform the at least one statistical operation based on the output signals by coherently summing the output signals via the summing arrangement.

10. The arrangement according to claim 1, wherein each quantum computing unit in the plurality of quantum computing units further comprises a plurality of frequency tuning elements configured to tune qubit frequencies of the plurality of qubits according to a frequency tuning signal.

11. The arrangement according to claim 1, wherein each quantum computing unit in the plurality of quantum computing units further comprises a plurality of capacitance tuning elements configured to tune capacitances of the plurality of qubits according to a capacitance tuning signal.

12. The arrangement according to claim 1, wherein the plurality of qubits comprises superconducting qubits.

13. The arrangement according to claim 1, wherein the at least one statistical operation comprises at least one of: a mean, a variance, and/or cross-entropy.

14. The arrangement according to claim 1 further comprising a cryostat, wherein the plurality of quantum computing units and the signal division arrangement are located inside the cryostat.

15. A quantum computing system comprising a plurality of arrangements according to claim 1.
